(19) United States
(12) Patent Application Publication
(10) Pub. No.: US 2008/0308042 A1
(43) Pub. Date: Dec. 18, 2008

(54) APPARATUS FOR PLASMA-PROCESSING FLEXIBLE PRINTED CIRCUIT BOARDS

(75) Inventors: ZE LONG, Shenzhen (CN); SZU-MIN HUANG, Tayuan (TW); CHIH-YI TU, Tayuan (TW)

Correspondence Address: PCE INDUSTRY, INC.;ATT. CHENG-JU CHIANG, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/024,948

(22) Filed: Feb. 1, 2008

(30) Foreign Application Priority Data
Jun. 15, 2007 (CN) 200710075059.7

(51) Int. Cl. H01L 21/687; H01L 21/00; C23C 16/00

(52) U.S. Cl. 118/728; 156/345.51; 118/723 R

(57) ABSTRACT

The present invention relates to an apparatus for plasma-processing of flexible printed circuit boards (FPCBs). The apparatus includes a plasma-discharging chamber, two electrodes arranged in the chamber for generating plasma in the chamber, a frame, and two elongated holding arms disposed on the frame. The frame includes a number of spaced parallel first bars and a number of spaced parallel second bars. The first bars intersecting with the second bars. The elongated holding arms are substantially parallel with each other. Each of the arms has an inner sidewall. The inner sidewalls of the elongated holding arms are opposite to each other. An elongated recess is defined in each of the inner sidewalls proximate to the frame. The apparatus can ensure uniform plasma-processing and protect FPCBs from being burned.

### BACKGROUND

1. Technical Field

The present invention relates to an apparatus for manufacturing printed circuit boards and, more particularly, relates to an apparatus for plasma-processing of flexible printed circuit boards (FPCBs) during manufacturing.

2. Discussion of Related Art

FPCBs have been widely used in electronic products such as mobile phones, printing heads and hard disks. In these electronic products, some parts may move relative to a main body. In such circumstance, FPCBs are advantageously employed to provide electrical connections and signal transmissions between such parts and the main body due to their excellent flexibility.

Generally, FPCBs are made from copper clad laminates (CCLs). In a typical process of manufacturing FPCBs, the CCLs are cleaned and then laminated, photoresist is applied on surfaces of the laminated CCLs, and then the photoresist is exposed and developed according to a desired mask pattern. Finally, the copper foils in the CCLs are etched into conductive patterns. With respect to multilayer FPCBs, above processes will be repeated until a predetermined number of layers are obtained.

Nowadays, plasma is popularly used for many steps in manufacturing FPCBs due to its flexible characteristic. For example, plasma can be used to clean dust, form holes and eliminate inner-stress of FPCBs. Typically, plasma is produced in a plasma-discharging chamber, which is filled with an inert gas, such as argon, at a low pressure. Two electrodes are provided in the chamber, where a high voltage is applied between the two electrodes. As a result, tip-discharging will occur between the two electrodes and plasma is thereby produced. Usually, FPCBs are placed on a flat plate and then exposed to the produced plasma. However, edges of the FPCBs may be curled in the plasma processing operation due to their high flexibility, and the plasma can't be effectively applied on the curled/curved portion of the FPCBs. Additionally, part of the curled FPCBs may be raised near or even in contact with the electrodes, causing burning of the FPCBs.

Therefore, there is a desire to develop an apparatus for plasma-processing of FPCBs that can improve uniformity of processing and protect FPCBs from being burned.

### SUMMARY

In one embodiment, an apparatus for plasma-processing of FPCBs includes a plasma-discharging chamber, two electrodes arranged in the chamber for generating plasma in the chamber, a frame, and two elongated holding arms disposed on the frame. The frame includes a number of spaced parallel first bars and a number of spaced parallel second bars. The first bars intersecting with the second bars. The elongated holding arms are substantially parallel with each other. Each of the arms has an inner sidewall. The inner sidewalls of the elongated holding arms are opposite to each other. An elongated recess is defined in each of the inner sidewalls proximate to the frame.

This and other features and advantages of the present invention as well as the preferred embodiments thereof and a frame in accordance with the invention will become apparent from the following detailed description and the descriptions of the drawings.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention.

FIG. 1 illustrates an apparatus for plasma-processing of FPCBs including a holder.

FIG. 2 is a schematic view illustrating the holder in FIG. 1.

FIG. 3 is a cross sectional view of the holder of FIG. 2.

FIG. 4 is an enlarged section view of area IV of FIG. 3.

FIG. 5 illustrates an FPCB is held in the holder of FIG. 2.

FIGS. 6 and 7 are similar to FIG. 4 but showing alternative structure of a holding arm in FIG. 4.

FIG. 8 illustrates a holder in accordance with a second embodiment;

FIG. 9 is a cross sectional view of FIG. 8 along line IX-IX; and

FIG. 10 is similar to FIG. 9 but showing two FPCBs held in the holder of FIG. 8.

### DETAILED DESCRIPTION OF THE PREFERRED EMBODIMENTS

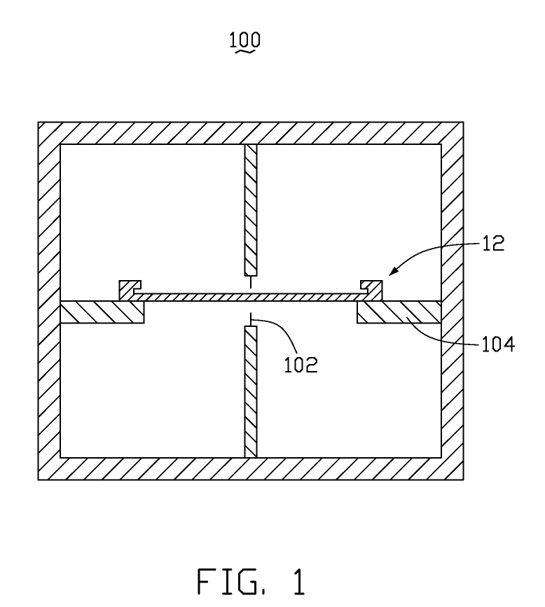

FIG. 1 illustrates an apparatus 100 for plasma-processing of FPCBs, the apparatus 100 includes a chamber 10 and a frame 12 disposed in the chamber 10. The frame 12 is disposed on a base plate 104, which is fixed to an inner sidewall of the chamber 10. Two electrodes 102 are arranged at opposite sides of the frame 12. However, it is understood that, the electrodes 102 can also be arranged at one side of the frame 12.

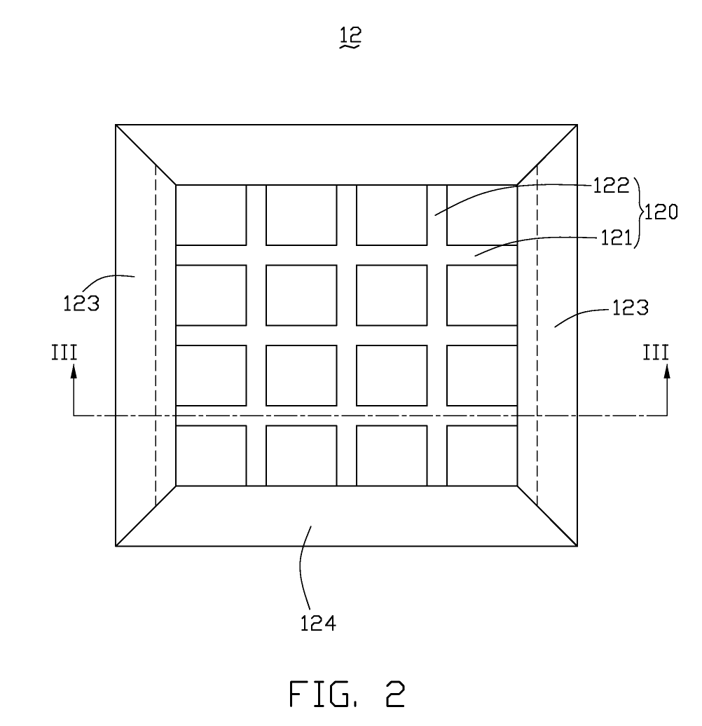

Referring to FIG. 2, the holder 12 includes a frame 120, two elongated holding arms 123 disposed on the frame 120, and two barriers 124 disposed on the frame 120. The frame 120 includes a number of spaced parallel first bars 121, and a number of spaced parallel second bars 122. Preferably, the spacing between the first bars 121 and between the second bars 122 is uniform. The first bars 121 perpendicularly intersect the second bars 122 thereby defining a number of through holes 106 in the frame. The two holding arms 123 are substantially parallel with each other. The first bars 121, second bars 122, the holding arms 123, and the barriers 124 can be made of a material selected from the group consisting of iron, steel, copper, aluminum, aluminum alloy, and magnesium alloy.

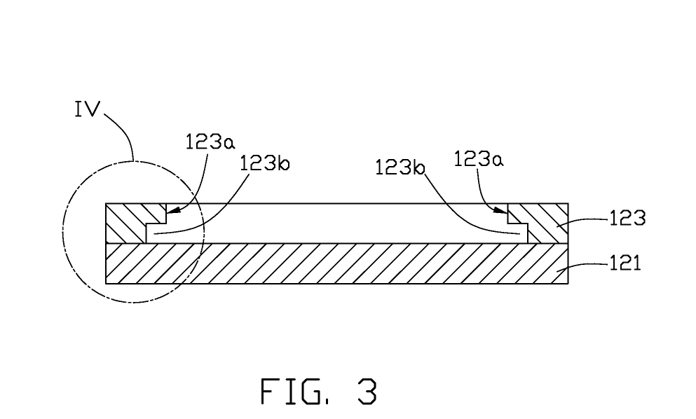

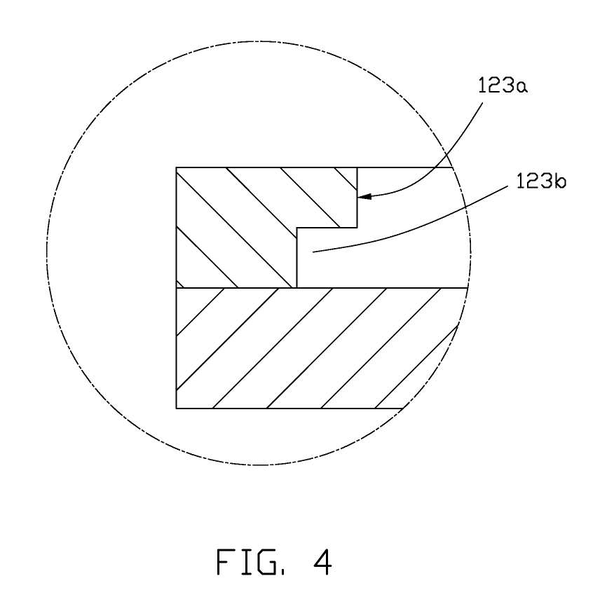

Referring to FIGS. 3 and 4, each holding arm 123 includes an inner sidewall 123a. The inner sidewalls 123a of the two holding arms 123 are opposite to each other. An elongated recess 123b is formed in the inner sidewall 123a of each holding arm 123. The elongated recess 123 extends in a lengthways direction of the corresponding holding arm 123. The elongated recesses 123 of the two holding arms 123 are configured for holding opposite ends of FPCBs. In the first embodiment, a cross section of the elongated recess 123b is rectangular and the holding arm 123 is inverted-L shaped.

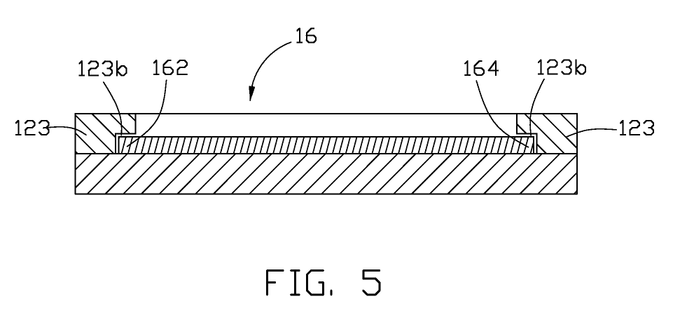

Referring to FIG. 5, a FPCB 16 is held in the holder 12. Two ends 162, 164 of the FPCB 16 are received in the recesses 123b of the two holding arms 123 respectively. If the holder 12 is disposed in a plasma discharging chamber, two surfaces of the FPCB 16 can be exposed to the plasma, as a result, two surfaces of the FPCB 16 can be processed simultaneously. The two holding arms 123 hold opposite ends of the FPCB such that the two ends of the FPCB can't bend, the electrode 102 in the plasma-discharging chamber 10 won't contact with the FPCB 16; therefore the FPCB 16 is protected from being burned. Furthermore, the FPCB can maintain a flat shape, resulting in uniform plasma-processing.

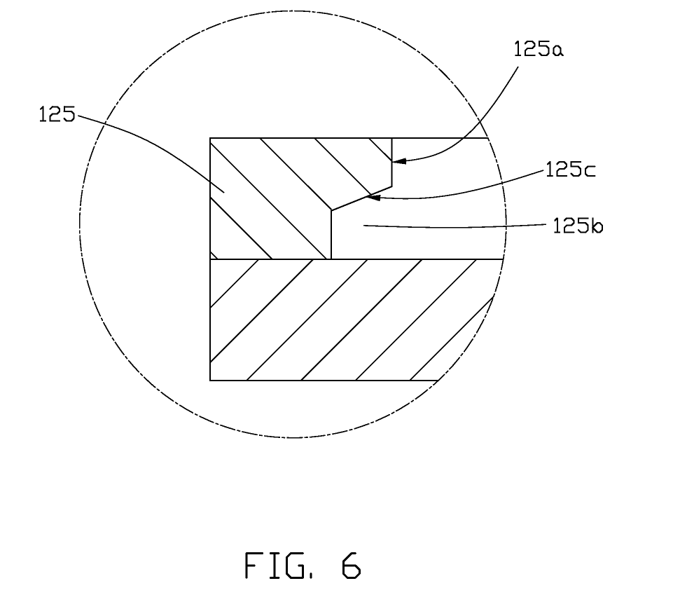

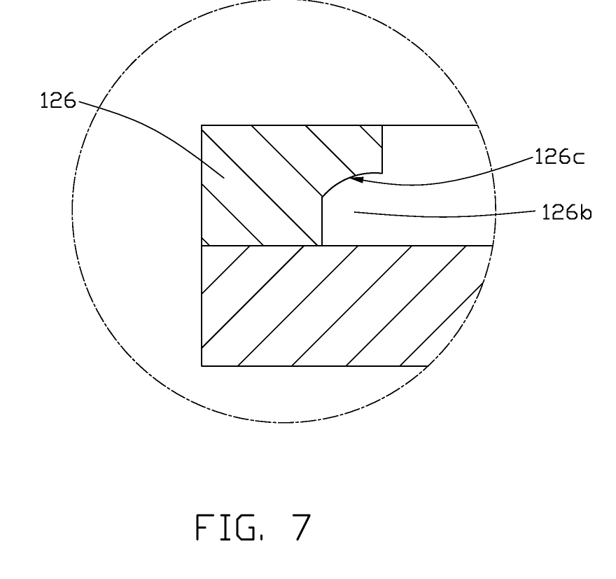

FIGS. 6 and 7 show alternative designs for the recesses 123b in FIG. 3. In FIG. 6, the cross-section of the recess 125b of the holding arm 125 is trapezoidal. A sidewall 125c extends from the sidewall 125a to the bottom surface 125d of the recess 125b. The holding arm 126 as shown in FIG. 7 is similar to that of the FIG. 6 except that the sidewall 126c has an arced surface. The holding arms 125, 126, and the recesses 125b, 126b are trapeziform or trapeziform-like in shape, an end of an FPCB can easily slide into the recesses 125b, 126b.

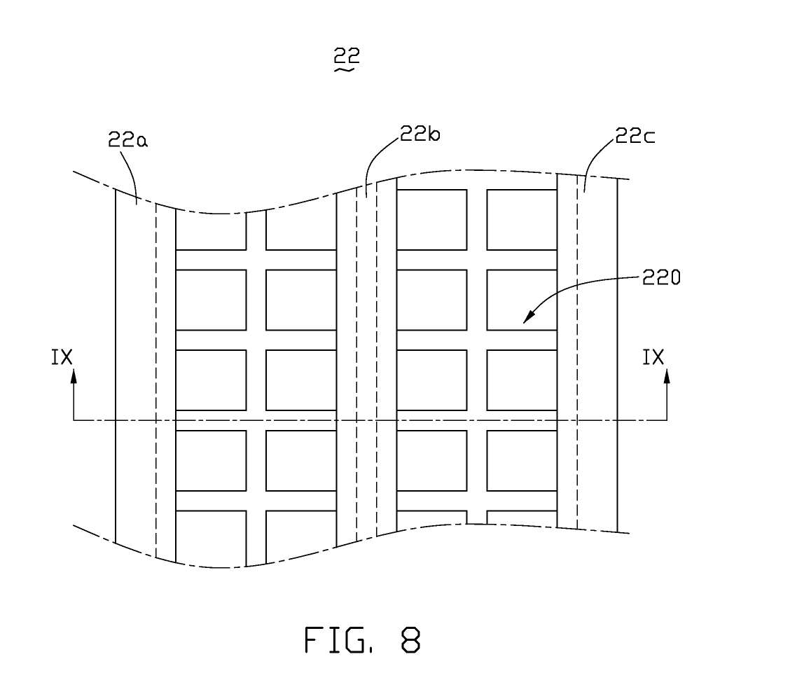

FIG. 8 illustrates a holder 22 in accordance with a second embodiment. The holder 22 is similar to the holder 12 except that the holder 22 includes three holding arms 22a, 22b, and 22c. The three holding arms 22a, 22b, and 22c are disposed on the frame 220 at equal intervals.

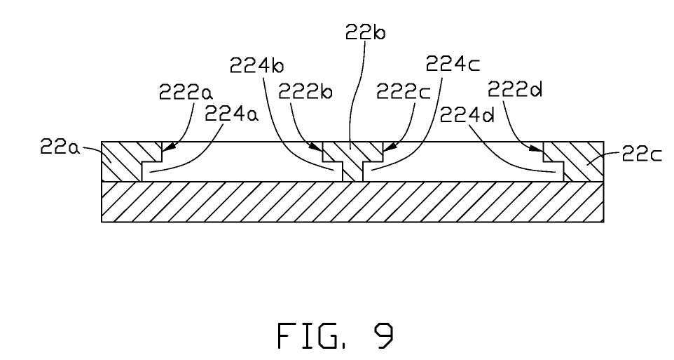

Referring to FIG. 9, the holding arm 22a includes a side wall 222a. The holding arm 22b includes opposite sidewalls 222b and 222c. The holding arm 22c includes a sidewall 222d. The sidewall 222a is opposite to the sidewall 222b, and the sidewall 222c is opposite to the sidewall 222d. Four recesses 224a, 224b, 224c, and 224d are formed in the sidewalls 222a, 222b, 222c, and 222d respectively. In the second embodiment, a cross section of the holding arm 22a is inverted-L shaped. A cross section of the holding arm 22b is T-shaped. A cross section of the holding arm 22c has a flipped inverted “L” shape. However, it is understood that cross-sections of the recesses 224a, 224b, 224c, and 224c can have trapeziform or trapeziform-like shapes, as shown in FIGS. 6 and 7.

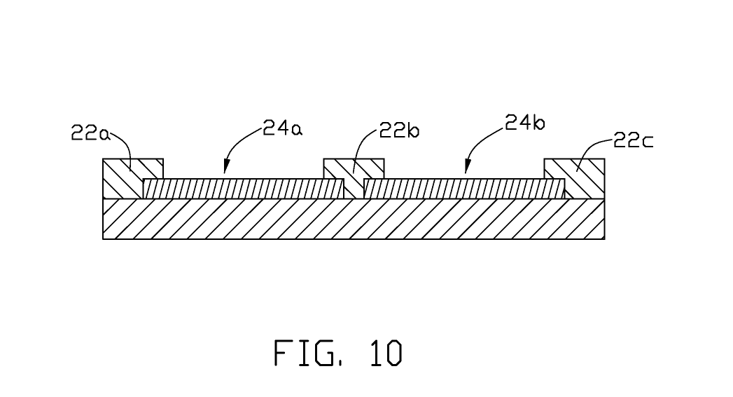

Referring to FIG. 10, two FPCBs 24a and 24b are held in the holder 22. The FPCB 24a is held between the holding arms 22a and 22b. The FPCB 24b is held between the holding arms 22b and 22c. In the second embodiment, the holder 22 includes three holding arms 22a, 22b, and 22c; as a result, the holder 22 is capable of holding two columns of FPCBs. It is to be understood that the holder 22 can include more holding arms, for example, four, five or more holding arms. Generally, a holder including N holding arms can hold N−1 columns of FPCBs, wherein N represents an integer larger than 2.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. An apparatus for processing a flexible printed circuit board comprising:
a plasma-discharging chamber,
two electrodes arranged in the chamber for generating plasma in the chamber,
a frame comprising a plurality of spaced parallel first bars and a plurality of spaced parallel second bars, the first bars intersecting with the second bars; and
two elongated holding arms disposed on the frame, the elongated holding arms being substantially parallel with each other, each of the arms having an inner sidewall, the inner sidewalls of the elongated holding arms opposite to each other, an elongated recess is defined in each of the inner sidewalls proximate to the frame, the elongated holding arms being configured for holding opposite ends of the flexible printed circuit board.

2. The apparatus for holding flexible printed circuit board as claimed in claim 1, further comprising two barriers, the holding arms and the two barriers cooperatively forming an enclosed sidewall on the frame.

3. The apparatus for holding flexible printed circuit board as claimed in claim 1, wherein the first and second bars are welded to each other

4. The apparatus for holding flexible printed circuit board as claimed in claim 1, wherein the frame is comprised of a material selected from the group consisting of iron, steel, copper, aluminum, aluminum alloy, and magnesium alloy.

5. The apparatus for holding flexible printed circuit board as claimed in claim 4, wherein the first and second bars are equidistantly spaced.

6. The apparatus for holding flexible printed circuit board as claimed in claim 1, wherein the holding arms are comprised of a material selected from the group consisting of iron, steel, copper, aluminum, aluminum alloy, and magnesium alloy.

7. The apparatus for holding flexible printed circuit board as claimed in claim 1, wherein the cross-section of the recess is rectangular shaped.

8. The apparatus for holding flexible printed circuit board as claimed in claim 1, wherein the cross-section of the recess is substantially trapezoid shaped.

9. The apparatus for holding flexible printed circuit board as claimed in claim 1, wherein the frame is disposed on a base plate, the base plate is fixed to an inner sidewall of the plasma-discharging chamber.
